(19) United States
(12) Patent Application Publication
(10) Pub. No.: US 2015/0362267 A1
(43) Pub. Date: Dec. 17, 2015

(54) High Temperature Heat Exchanger

(71) Applicants: ROBERT BOSCH GMBH, Stuttgart (DE); SAMSUNG SDI CO., LTD., Yongin-si, Gyeonggi-do (KR)

(72) Inventor: Stephan Leuthner, Leonberg (DE)

(21) Appl. No.: 14/763,437

(22) PCT Filed: Nov. 26, 2013
(86) PCT No.: PCT/EP2013/074676

§ 371 Date: Jul. 24, 2015

(30) Foreign Application Priority Data
Jan. 24, 2013 (DE) 10 2013 201 128.8

(51) Int. Cl. F28F 21/04; H01L 35/30; F28F 13/00

(52) U.S. Cl. CPC F28F 21/04; F28F 13/00; H01L 35/30

(57) ABSTRACT

A high-temperature heat exchanger comprises a thermally insulated solid body formed from a high temperature resistant material with a thermal conductivity of at least 20 W/mK, at least one heater element within the solid body; and passages for fluid flow formed in the solid body. A system is also disclosed that comprises high-temperature heat exchanger in a thermo-management circuit of a battery.

### BACKGROUND OF THE INVENTION

The invention relates to a high-temperature heat exchanger and also to a use of the high-temperature heat exchanger.

High-temperature heat exchangers are used for example in order to absorb heat from electric heater bars. Such electric heater bars are used for example in hybrid or electric vehicles in order to absorb surplus electrical energy which for example is created during recuperation in an electric generator. The surplus electrical energy is created in this case if the electrical energy accumulator is fully charged or the temperature of batteries, for example, is excessively low. The use of such electric heater bars is described in DE-A 2007 032 726, for example. In this case, it is also disclosed that a plurality of heater bars can be used, wherein for example different components can be heated by a plurality of heater elements.

When using lithium-ion batteries at low temperatures, the upper voltage limit of the battery is reached very quickly when electrical energy is being supplied and the battery would then have to be quickly limited. Moreover, at low temperatures in lithium-ion batteries lithium plating can occur, as a result of which lithium deposits are created on the anode. These deposits are safety-critical if needle-like lithium crystals form on the anode. These can pierce the separator, which as a result leads to short circuits. Furthermore, the deposited lithium can also react with the electrolytes, as a result of which the battery increasingly dries out. This phenomenon then leads to accelerated aging of the lithium-ion battery. Therefore, it is of great interest to heat a very cold battery, that is to say a battery with a temperature of less than 0° C., as quickly as possible.

For heating the very cold battery, a liquid heat transfer agent is customarily used. This can be heated by electric heater bars, for example. To this end, the liquid heat transfer agent is usually made to flow around the heater bars. If during recuperation high electrical outputs are fed to the heater bar and converted into heat, this heat has to be dissipated to the environment. In the case of a high thermal output, this can lead to liquid which flows around the heater bar evaporating in an uncontrolled manner. This, moreover, can lead to undesirable acoustic accompanying effects. The liquid which is heated in this way is then used in order to heat the battery.

### DISCLOSURE OF THE INVENTION

### Advantages of the Invention

A high-temperature heat exchanger according to the invention comprises a solid body consisting of a good heat conducting and temperature resistant material, with at least one heater element introduced therein, wherein passages, through which a fluid can flow, are formed in the solid body and wherein the solid body is thermally insulated.

By using a good heat conducting solid body, the heat from the heater element is released and at the same time the disadvantages of using a liquid are avoided. By using the solid body, the effect of fluid evaporating in an uncontrolled manner is especially avoided. A further advantage, when using a good heat conducting solid body, is that heat can be released from the at least one heater element in a small area so that the high-temperature heat exchanger can also be of a correspondingly small construction. “Good heat conducting” within the scope of the present invention means that the thermal conductivity is at least 20 W/mK, preferably at least 150 W/mK.

“High temperature resistant” within the scope of the present invention means that the material is not damaged at the temperatures which can be achieved by the heater bar. A heater element can for example in this case achieve temperatures of up to 700° C., even up to 1200° C. in the case of special applications.

The heater element which is introduced into the solid body is generally an electric heater element. Suitable heater elements are for example electric heater bars or heater mats. The heater element can also be a heater cartridge.

In order to be able to use the high-temperature heat exchanger, the passages which are introduced into the solid body are connected to an inlet and to an outlet for the throughflowing fluid. If more than one passage is accommodated in the solid body, then the inlet preferably has a distributor and the outlet preferably has a collector so that the fluid can flow through all the passages. Alternatively, it is also possible to provide a plurality of inlets and a plurality of outlets. The fluid which flows through the solid body is preferably a gas, for example air. When a gas is being used, it avoids the effect of fluid rapidly evaporating and this leading to evaporation shocks and consequently to acoustic accompanying phenomena or pressure shocks in fluid lines. Such acoustic accompanying phenomena and pressure shocks also occur in the case of the systems which are known from the prior art in which the fluid is heated directly by the heater bar. These are also avoided as a result of the high-temperature heat exchanger according to the invention.

A further advantage of using the solid body is that large thermal capacities can be transferred to this. In this case, the solid body generally heats up. Due to the fact that the solid body heats up, the mass of the actual solid body, to which the energy of the heater element is transferred, can be minimized. With a high thermal conductivity of the solid body, moreover, a highest possible level of efficiency is achieved. Since the solid body heats up, this can also be used at the same time as a heat accumulator and the heat can be used in a manner in which it is distributed over a longer period of time. Solid bodies which have a large thermal capacity are particularly well suited as heat accumulators.

As material for the solid body, according to the invention a good heat conducting, high temperature resistant material is used. This is preferably a ceramic. Especially preferred are ceramics which are built on a base of silicon carbide. As a result, the silicon-carbide ceramics have for example a thermal conductivity of up to 350 W/mK.

In order to be able to further utilize the heat which is yielded to the fluid, it is furthermore preferred if the outlet for the throughflowing fluid is connected to an additional heat exchanger, wherein the fluid which has flown through the solid body and been heated yields heat to a heat transfer agent. The heat transfer agent which is heated in this way in the heat exchanger can then be used for heating a component, for example a lithium-ion battery. The heat transfer agent, which is heated in the additional heat exchanger by the fluid, is preferably a liquid.

In addition to using a liquid heat transfer agent for the thermo-management battery system of a battery, a gaseous heat transfer agent, for example air, can also be used. However, the use of a liquid heat transfer agent, for example a water-ethylene glycol mixture, is preferred.

If a single throughflow of the solid body by the fluid to heat up the fluid to the desired temperature is not achieved, it is furthermore preferred to provide a bypass which branches from the outlet and opens into the inlet. Some of the fluid or even all of the fluid can then flow through the bypass and once more through the solid body, as a result of which this is heated up further.

If the thermal capacity of the solid body is sufficiently large, this can also be used as a heat accumulator. In an embodiment of the invention, the solid body contains at least one additional heat storage material. Also suitable as heat storage material are for example phase change materials which at a specific temperature can absorb a particularly large amount of heat as a result of a phase conversion from solid to liquid.

The high-temperature heat exchanger is especially preferably used for the temperature regulation of a battery, especially a lithium-ion battery. To this end, the high-temperature heat exchanger is connected to the thermo-management circuit for the battery. To this end, it is possible, for example, as already previously described, to direct the fluid flowing through the passages in the solid body into an additional heat exchanger in which the heat from the fluid is yielded to a liquid heat transfer agent which is used to heat the battery. If the battery is completely charged, it is also possible to also utilize the heat for heating additional components or also for heating the interior of the vehicle.

In a further embodiment, the high-temperature heat exchanger is coupled to a thermoelectric generator. As a result of the coupling to the thermoelectric generator, it is possible to reconvert some of the heat which is stored in the solid body into electrical energy. This electrical energy can be used in order to recharge the battery or alternatively also used directly for operating electrically operated components.

### BRIEF DESCRIPTION OF THE FIGURES

An exemplary embodiment of the invention is shown in the FIGURE and is explained in more detail in the following description.

The single FIGURE shows a schematic representation of the high-temperature heat exchanger according to the invention.

### EXEMPLARY EMBODIMENT OF THE INVENTION

Shown schematically in the single FIGURE is a high-temperature heat exchanger which is designed according to the invention.

A high-temperature heat exchanger 1 comprises a solid body 3 in which are accommodated heater elements 5. The solid body 3 encloses the heater elements 5 so that heat from the heater elements 5 can be transferred directly to the solid body 3. The solid body 3 in this case is produced from a good heat conducting, high temperature resistant material. As material for the solid body, ceramics, especially good heat conducting ceramics, for example ceramics on a base of silicon carbide, are especially suitable. In addition to ceramics, high-melting metals or metal alloys, for example, are also suitable as material for the solid body. High-melting in this case means that the melting temperature is higher than 750° C. In addition to silicon carbide, aluminum nitride, for example, is suitable as the ceramic.

The heater elements 5, which are enclosed by the solid body 3, are for example electric heater bars, heater cartridges or heater mats. The energy which is produced during operation of the heater elements can be produced for example when using the high-temperature heat exchanger 1 in a hybrid or electric vehicle, during recuperation in an electric generator of said hybrid or electric vehicle.

The heat of the heater elements 5 is then transferred to the solid body 3. If a material which has a sufficiently good heat capacity is selected for the solid body 3, the solid body 3 can also be used as a heat accumulator. For improving the heat storage capability of the solid body 3, it is furthermore also possible to introduce a heat storage material into the solid body 3. Suitable as heat storage material are for example phase change materials which by heat absorption at a specific temperature carry out a phase conversion from solid to liquid. As a result of the phase conversion, these materials can absorb a particularly large amount of heat. The heat which is absorbed by the phase change materials can then be released again by means of a reconversion from liquid to solid. The heat which is released in this way can be used for example for heating purposes or alternatively also for operating thermoelectric generators. With the thermoelectric generators, electrical energy can then be generated by means of the heat.

In order to avoid the heat from the solid body 3 being dissipated to the environment, the solid body 3 is provided with an insulation 7. As material for the insulation 7, any chosen heat insulating material which is known to the person skilled in the art is suitable.

In order to be able to utilize the heat which is transferred from the heater elements 5 to the solid body 3, according to the invention passages 9 are formed in the solid body 3. Fluid can flow through the passages 9 for absorbing the heat. The flow through the passages 9 is preferably by a gas, especially air, which absorbs the heat from the solid body 3. By using a gas as fluid for absorbing the heat the effect of a liquid evaporating in an uncontrolled manner is avoided so that evaporation shocks and consequently acoustic accompanying phenomena or pressure shocks in the fluid lines can be avoided.

The passages 9 which are introduced into the solid body can be designed both in the form of holes, for example with a round cross section, or as passages with an angular cross section. If the passages 9 have an angular cross section, this can have a width which is considerably larger in comparison to the height. In this case, it is also possible for example to design the solid body 3 in the form of individual plates, wherein a heater element 5 is preferably accommodated in each plate and the individual plates are separated in each case by a passage 9. In addition to a complete separation of the individual plates of the solid body 3 by means of the passages 9, it is also possible to provide ribs, for example, by means of which the individual solid body elements are interconnected. The ribs can be used on the one hand for separating individual passages 9 or alternatively provision can also be made in a passage for individual ribs around which the fluid can flow.

If the individual solid body elements are interconnected by ribs, it is not necessary to provide a heater element 5 in each solid body element either. In this case, the heat is distributed via the ribs to individual solid body elements.

In order to conduct the fluid uniformly through the passages 9, the passages 9 are connected on the inlet side to a distributor 11 and connected on the outlet side to a collector 13.

For operating the high-temperature heat exchanger 1, gas, preferably air, is conducted by means of a blower 15 through a feed line 17 into the collector 11, and from there further conducted into the passages 9. Heat which is transferred from the heater elements 5 to the solid body 3 is absorbed by the gas flowing through the passages 9. The heated gas is conducted via the collector 13 into a line 19, and from there further conducted into a heat exchanger 21. In the heat exchanger 21, a heat transfer agent for example is heated for a subsequent application. To this end, the heat transfer agent is conducted via lines 23 through the heat exchanger 21.

The subsequent application, for which the heat transfer agent which is conducted through the line 23 is used, is for example a thermo-management circuit, for example for a battery, as is used in hybrid or electric vehicles. In this case, it is usually a lithium-ion battery. Especially when the battery is being charged it is necessary to heat the battery as quickly as possible in order to avoid the occurrence of lithium plating at low temperatures and the formation of needle-like lithium crystals on the anode which pierce the separator and consequently can lead to short circuits.

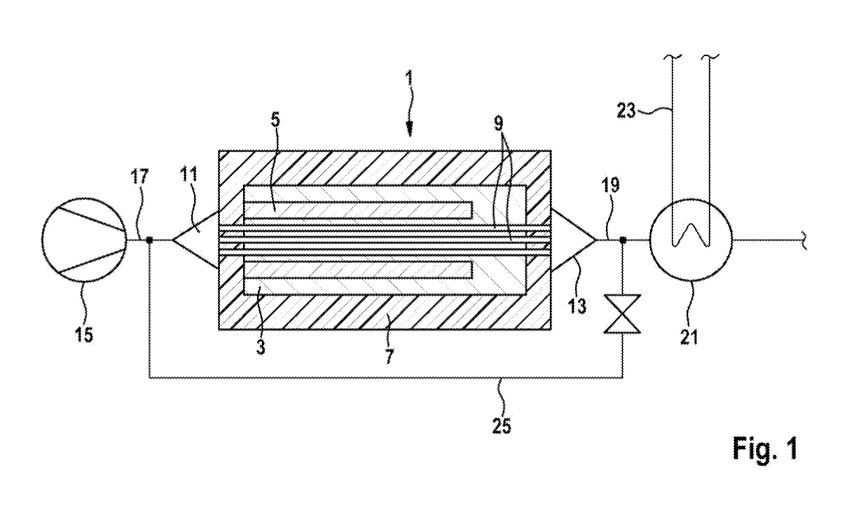

If a smaller amount of heat is released from the heater elements 5 and the heat is not enough to sufficiently heat up the fluid flowing through the passages 9, it is advantageous if a bypass 25 is provided, as shown in FIG. 1. In order to bring the fluid to the desired temperature, some of the fluid can be conducted through the bypass 25 back into the feed line 17 and from there through the high-temperature heat exchanger 1 again. As a result of this, the fluid is further cooled. The fluid which leaves the high-temperature heat exchanger 1 therefore has a higher temperature than in the case of an only single pass through the high-temperature heat exchanger 1. When using the bypass 25, the fluid which is already heated and conducted back through the bypass 25 is mixed in the process with the fluid which is freshly supplied by means of the blower 15.

After flowing through the heat exchanger 21, the fluid, providing the temperature of the fluid is still high enough, can be used for downstream applications, for example for temperature regulation of the interior of a motor vehicle or for heating other components in the hybrid or electric vehicle.

1. A high-temperature heat exchanger, comprising:
a thermally insulated solid body formed from a high temperature resistant material with a thermal conductivity of at least 20 W/mK;
at least one heater element within the solid body; and
passages for fluid flow formed in the solid body.

2. The high-temperature heat exchanger as claimed in claim 1, wherein the good material is a ceramic.

3. The high-temperature heat exchanger as claimed in claim 1, wherein the at least one heater element is an electric heater bar.

4. The high-temperature heat exchanger as claimed in claim 1, further comprising:
a feed line and an outlet, the passages connected to the feed line and to the outlet for a throughflowing fluid.

5. The high-temperature heat exchanger as claimed in claim 4, wherein the outlet is connected to an additional heat exchanger having a heat transfer agent, and fluid which has flowed through the solid body and been heated transfers heat to the heat transfer agent in the heat exchanger.

6. The high-temperature heat exchanger as claimed in claim 5, further comprising a bypass that branches from the outlet and opens into the feed line.

7. The high-temperature heat exchanger as claimed in claim 1, further comprising a heat storage material contained in the solid body.

8. The high-temperature heat exchanger as claimed in claim 7, wherein the heat storage material is a phase change material.

9. The high-temperature heat exchanger as claimed in claim 1, wherein the high-temperature heat exchanger is coupled to a thermoelectric generator.

10. A system, comprising:
a high-temperature heat exchanger including a thermally insulated solid body formed from a high temperature resistant material with a thermal conductivity of at least 20 W/mK,
at least one heater element within the solid body, and passages for fluid flow formed in the solid body; and
a battery, including a thermo-management circuit, the high-temperature heat exchanger position in the thermo-management circuit.

11. The high-temperature heat exchanger as claimed in claim 2, wherein the material is a ceramic formed on a base of silicon carbide.

12. The high-temperature heat exchanger as claimed in claim 1, wherein the at least one heater element is a heater mat.

13. The system of claim 10, wherein the battery is a lithium-ion battery.

14. The high-temperature heat exchanger as claimed in claim 1, wherein the material has a thermal conductivity of at least 150 W/mK.

15. The system of claim 10, wherein the material has a thermal conductivity of at least 150 W/mK.

16. The high-temperature heat exchanger as claimed in claim 1, wherein the high temperature resistant material is configured to withstand heat from the at least one heater element.

17. The system of claim 10, wherein the high temperature resistant material is configured to withstand heat from the at least one heater element.
